(19) United States
(12) Patent Application Publication
(10) Pub. No.: US 2025/0264373 A1
(43) Pub. Date: Aug. 21, 2025

(54) TESTING SYSTEM AND METHOD OF CURVED DISPLAYING APPARATUS

(71) Applicant: SAMSUNG DISPLAY CO., LTD., YONGIN-SI (KR)

(72) Inventors: KIWOOK LEE, Yongin-si (KR); JIN HO CHOI, Yongin-si (KR); HEE DOK CHOI, Yongin-si (KR)

(21) Appl. No.: 18/926,547

(22) Filed: Oct. 25, 2024

(30) Foreign Application Priority Data
Feb. 20, 2024 (KR) 10-2024-0024568

(51) Int. Cl. G01M 11/08; G01M 5/00; G02F 1/13; G02F 1/1333; H10K 71/70; H10K 102/00

(52) U.S. Cl. CPC G01M 11/08; G01M 5/0033; G01M 5/0075; G02F 1/1309; G02F 1/133305; H10K 71/70; H10K 2102/311

(57) ABSTRACT

An inspection system for a display device includes a plurality of support members supporting a bottom of an inspection panel of the display device. A plurality of imaging devices captures images of four corners of the inspection panel. A position misalignment confirmation unit verifies a misaligned direction of the inspection panel based on gray values of the four corner images of the inspection panel. A control unit corrects a misalignment of the inspection panel determined by the position misalignment confirmation unit. The control unit controls support member driving means that drives the plurality of support members to correct the misalignment.

### CROSS-REFERENCE TO RELATED APPLICATION

This application claims priority under 35 U.S.C. § 119 to Korean Patent Application No. 10-2024-0024568, filed on Feb. 20, 2024 in the Korean Intellectual Property Office, the disclosure of which is incorporated by reference in its entirety herein.

### 1. TECHNICAL FIELD

The present disclosure relates to an inspection system and method for a curved display device, and more specifically, to an inspection system and method for a curved display panel.

### 2. DISCUSSION OF RELATED ART

There are various types of display devices in the electronic products industry, including liquid crystal displays (LCD) and organic light emitting diodes (OLED). The liquid crystal display (LCD) includes a liquid crystal display panel that utilizes the light transmittance of liquid crystals to display images. A backlight assembly is positioned below the liquid crystal display panel to provide light.

The organic light emitting diode (OLED) is a self-emissive display device which displays images using organic light emitting diodes (OLEDs) that emit light through the recombination of electrons and holes, without requiring a backlight assembly. Organic light emitting diodes have been widely used in the electronic products industry because they provide relatively fast response speeds and operate with relatively low power consumption.

Curved display devices in which the edges of the screen are curved towards the user are being developed to provide users with a wider field of view for the user. The curved display device increases image viewing with wider angles and increased depth perceptions.

Curved display devices are being developed in various sizes, curvatures, and resolutions suitable for various fields, including TVs, monitors, smart phones, and wearable electronic devices.

The curved display device uses a flexible display panel that requires inspection for a bending defect. However automation of the inspection is difficult due to the characteristics of flexible display panels.

For example, to automate the inspection of the bending defect in flexible display panels, the flexible display panel must move seamlessly, but due to the curved features, stop loss may occur.

Furthermore, expanding the vision imaging area to identify alignment marks for bending defect inspection in flexible display panels results in a larger inspection system for curved display devices.

### SUMMARY

The present disclosure is designed to solve these problems, and the objective of the present disclosure is to provide an inspection system and method for a curved display device that can automate the inspection of bending defects in flexible display panels used in curved display devices.

According to an embodiment of the present disclosure, an inspection system for a display device includes a plurality of support members supporting a bottom of an inspection panel of the display device. A plurality of imaging devices captures images of four corners of the inspection panel. A position misalignment confirmation unit verifies a misaligned direction of the inspection panel based on gray values of the four corner images of the inspection panel. A control unit corrects a misalignment of the inspection panel determined by the position misalignment confirmation unit. The control unit controls support member driving means that drives the plurality of support members to correct the misalignment.

According to an embodiment of the present disclosure, an inspection system for a display device includes a bending inspection device that inspects a bending defect of an inspection panel of the display device. A transfer device loads, moves, and unloads the inspection panel to the bending inspection device. A control device controls the bending inspection device and the transfer device. The bending inspection device includes a pair of upper rollers fixing an upper portion of the inspection panel. A pair of lower rollers supports a lower portion of the inspection panel. A bending press member presses the upper roller vertically downward to bend the inspection panel. A plane return member returns a curved surface of the inspection panel to a plane surface after a process for inspecting defective bending of the inspection panel.

According to an embodiment of the present disclosure, a control method of a display device inspection system includes automatically loading an inspection panel into a correct position on the display device inspection system. A bending inspection process is performed on the loaded inspection panel. The loaded inspection panel is bent to have a curved surface during the bending inspection process. A process to return the curved surface of the inspection panel to a plane surface is performed after performing the bending inspection process. A position misalignment of the inspection panel that occurred during the process of returning the inspection panel to the plane surface is checked. A position alignment movement is performed to correct the position misalignment of the inspection panel and place the inspection panel into a correct position. The inspection panel is unloaded in the correct position.

In the control method of the display device inspection system according to an embodiment of one aspect of the present disclosure, the step of automatically loading the inspection panel in the correct position includes arranging the inspection panel with respect to a pair of support members supporting the inspection panel from the bottom, and the step of inspecting the bending defect may include the steps of pressing the inspection panel from above, and pressing a pair of fixing members positioned in the central area having a gap less than the gap between the pair of support members from above with a bending press member.

The control method of the display device inspection system according to an embodiment of one aspect of the present disclosure may include a process of returning to the plane surface, which includes a step of moving the bending press member upward and a step of pressing the curved surface of the inspection panel to the plane surface by the plane return member.

The step of checking the misalignment of the inspection panel may include imaging the four corners of the inspection panel before and after the bending defect inspection using a vision positioned below the four corners of the inspection panel, and comparing the four corners imaging before and after the bending process on a gray value basis.

According to the inspection system and method for the curved display device of the present disclosure, it is possible to automate the bending defect inspection in flexible display panels used in the curved display device.

According to the inspection system and method for the curved display device of the present disclosure, automating the bending defect inspection in the flexible display panel relies on seamless movement of the flexible display panel, resolving stop loss caused by the curved features of the flexible display panel.

Additionally, to identify alignment marks for bending defect inspection in a flexible display panel, the edges of the display panel are aligned with the alignment marks. Therefore, there is no need to enlarge the vision imaging area.

The display panel is aligned using the driving device of the lower roller, and since the position alignment motion is performed, there is no need to increase the size of the inspection system for the curved display device.

### BRIEF DESCRIPTION OF THE DRAWINGS

FIG. 1 is a conceptual diagram of an inspection system for a curved display device according to an embodiment of the present disclosure.

FIG. 2 to FIG. 5 are a perspective view, a front view, a perspective view from the bottom, and a side view of an inspection system, respectively, for the curved display device according to embodiments of the present disclosure.

FIG. 6 is a conceptual diagram of an inspection system for the curved display device according to an embodiment of the present disclosure.

FIG. 7 to FIG. 10 are a perspective view, a front view, a perspective view from the bottom, and a side view of an inspection system for the curved display device, respectively, according to embodiments of the present disclosure.

FIG. 11 is an abridged flow chart of a control method of the curved display device inspection system according to an embodiment of the present disclosure.

FIG. 12 is a detailed flow chart of the control method of the curved display device inspection system of an embodiment of the present disclosure.

FIG. 13 is a diagram explaining the concept of the position alignment motion method of FIG. 12 according to an embodiment of the present disclosure.

### DETAILED DESCRIPTION OF EMBODIMENTS

Hereinafter, non-limiting embodiments of the present disclosure will be described in detail with reference to the attached drawings.

However, the present disclosure may be implemented in various forms and is not limited to the embodiments described herein.

When it is said that a part “includes” a certain component throughout the specification, this means it may further include other components unless specifically stated to the contrary.

Additionally, throughout the specification, when a part such as a layer, membrane, region, or plate is said to be “above” or “on” another part, this does not only mean “right on top” or “directly on top” of the other part, but that there may be intervening elements therebetween. When a part such as a layer, membrane, region, or plate is said to be “directly above” or “directly on” another part, no intervening elements may be therebetween.

Furthermore, “above” or “on” means located above or below the target part, and does not necessarily mean located above based on the direction of gravity.

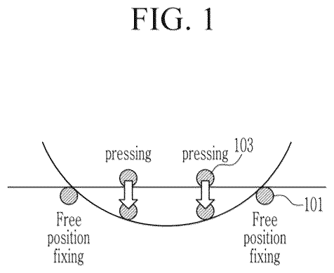

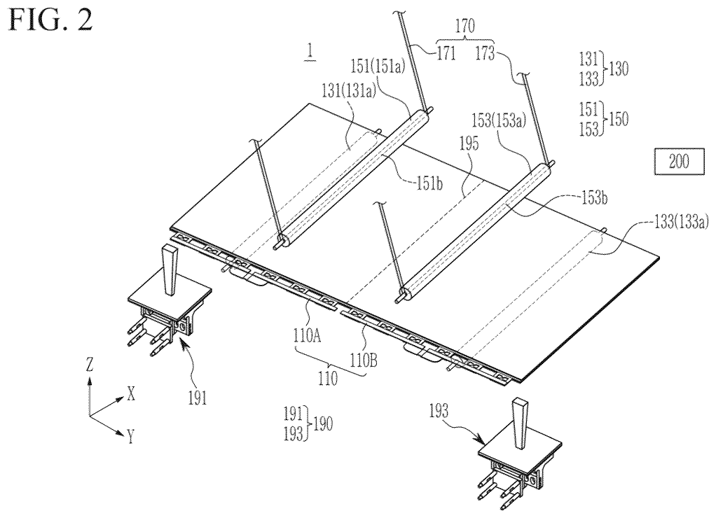

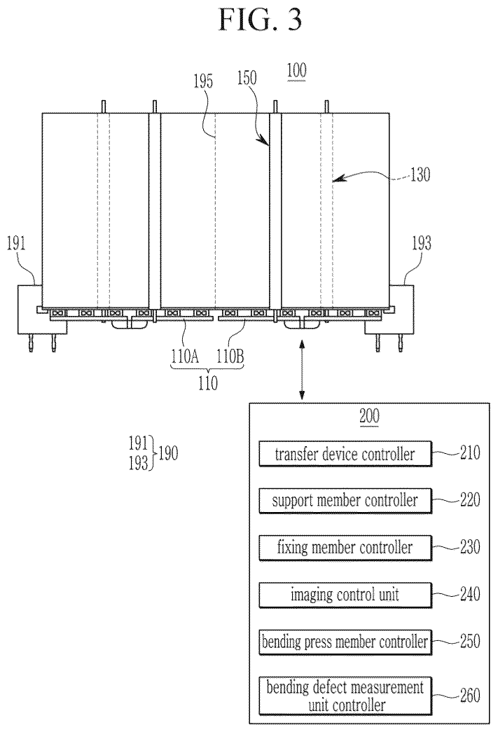

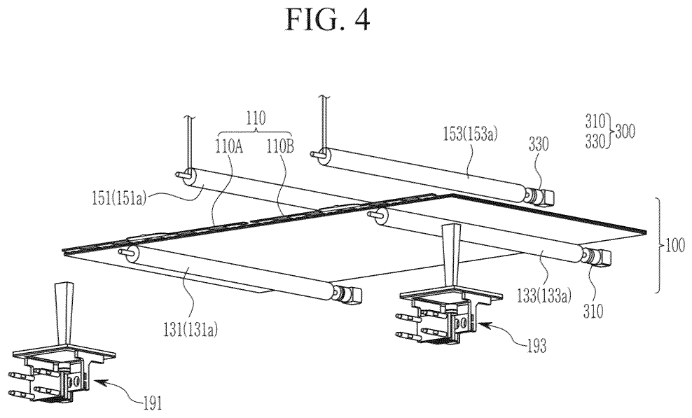

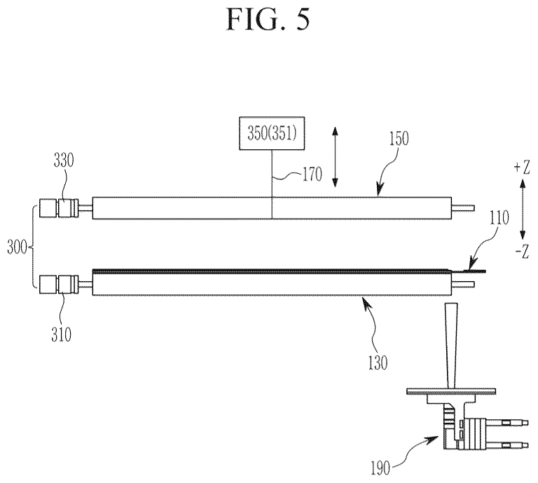

FIG. 1 is a conceptual diagram of the inspection system for the curved display device according to an embodiment of the present disclosure, while FIGS. 2 to 5 depict the perspective, front, bottom, and side views, respectively, of the inspection system for the curved display device according to an embodiment of the present disclosure.

Referring to FIG. 1, in the inspection system for the curved display device according to an embodiment of the present disclosure, a bending inspection device 100 for the flexible display panel performs a bending test set to simulate the application of the display panel in the curved display device. The bending inspection device 100 checks for bending defects while the display panel is bent under inspection.

For instance, in an embodiment the aforementioned display panel may have flexible characteristics, and depending on the bending strength, the substrate may fracture at the pressurized bending part, the bonded substrate may detach, cracks may develop, or bending defects such as stains may arise.

In an embodiment, the bending inspection device 100 performs bending inspection under bending inspection conditions by supporting the lower area of the display panel with two lower rollers and pressing the upper area with two upper rollers to achieve an inspection curvature that can be set to be larger or smaller than the target curvature of the curved display device.

A display panel that exhibits no defects under the bending test conditions may be classified as a normal, whereas a panel that exhibits a defect under the bending test conditions may be classified as abnormal.

The bending inspection device 100 may detect the maximum curvature condition under which no bending defect occurs, depending on the type of display panel, through the bending inspection process.

The maximum curvature condition can serve as basic data in the manufacturing process before and after the bending inspection process, thereby increasing process efficiency by providing optimal overall manufacturing process conditions.

As shown in FIGS. 2 to 4, the inspection system 1 for the curved display device according to an embodiment of the present disclosure includes the bending inspection device 100, a control device 200, and a transfer device 300.

In an embodiment, the bending inspection device 100 includes an inspection panel 110 composed of a driving IC 110A and a PCB 110B, a plurality of support members 131, 133 positioned below the inspection panel 110.

In an embodiment, the bending inspection device 100d may also include a plurality of detachable fixing members 151, 153 positioned on the inspection panel 110, bending press members 171, 173, and a bending defect measurement unit 190.

In an embodiment, the inspection panel 110 may be a display cell detached from the mother substrate.

The inspection panel may be a liquid crystal display cell or an organic light emitting display cell.

The inspection panel may be a display panel before an optical film such as a polarizer or protective film and circuit member such as a driving chip, are attached or it may be a display panel to which the optical film and the circuit member are already attached.

The plurality of support members 131, 133 are positioned below the inspection panel 110 (e.g., in the −Z direction) and support the inspection panel 110.

In an embodiment,, the plurality of support members 130 are positioned below the inspection panel 110 corresponding to edge areas on both sides (e.g., edge areas in the Y direction and −Y direction) rather than opposite sides of the inspection panel 110.

For instance, in an embodiment in which the inspection panel 110 is a rectangular shape and includes a relatively short side and a relatively long side, the first support members 131 among the plurality of support members 130 may be arranged to support the first edge area of the first relatively short side of the inspection panel 110 from below.

Similarly, the second support members 133 among the plurality of support members 130 may be arranged to support the second edge area of the second relatively short side of the inspection panel 110 that faces the first short side, from below.

The plurality of support members 131, 133 may support the inspection panel 110 during the bending defect inspection, and may include first and second roller parts, 131a, 133a that transfers the inspection panel 110 once the bending defect inspection is completed.

In an embodiment, the first and second roller parts, 131a, 133a, may be made from materials resistant to static electricity to reduce the occurrence of scratches caused by the inspection panel 110 moving diagonally rather than horizontally under the bending inspection conditions.

The plurality of detachable fixing members 151, 153, along with the plurality of support members 131, 133 may fix the loaded inspection panel 110 in a stationary position.

In an embodiment, the plurality of detachable fixing members 151, 153 may be positioned on the inspection panel 110 in pairs along with the plurality of support members 131, 133.

The plurality of fixing members 151, 153, like the plurality of support members 131, 132, are positioned on the inspection panel 110 corresponding to edge areas on both sides of the inspection panel 110 that face each other (e.g., edge areas in the Y direction and −Y direction).

For instance, in an embodiment in which the inspection panel 110 is a rectangular shape and includes a relatively short side and a relatively long side, the first fixing members 151 among the plurality of fixing members 150 of the inspection panel 110 may be arranged to support the first edge area on the relatively short side (e.g., the edge area in the −Y direction).

Similarly, the second fixing members 153 among the plurality of fixing members 150, are located on the second relatively short side of the inspection panel 110, facing the first short side, and may be arranged to support the second edge area of the relatively short side (e.g., the edge area in the Y direction).

In an embodiment, the plurality of detachable fixing members 151, 153 can fix the inspection panel 110 during the bending defect inspection, and the plurality of detachable fixing members 151, 153 may further include the third and fourth roller parts 151a, 153a for transporting the inspection panel 110 after the bending defect inspection is completed.

Like the first and second roller parts 131a, 133a, the third and fourth roller parts 151a, 151b can be made of a material that is resistant to static electricity so that the inspection panel 110 does not move diagonally under the bending inspection condition, to reduce the occurrence of scratches.

In an embodiment, the plurality of detachable fixing members 151, 153 are mounted on the inspection panel 110 in pairs with the plurality of support members 131, 133 to fix the inspection panel 110 before imaging the pressurized surface using the plurality of imaging devices 191, 193.

In an embodiment, the plurality of fixing members 151, 153 may be detached from the inspection panel 110 during the bending inspection process, where the inspection panel 110 is bent and moved to be mounted near a central area to facilitate the bending inspection process. In an embodiment, the bending press members 171, 173 may be coupled to the plurality of fixing members 151, 153 during the bending fixation process.

The plurality of fixing members 151, 153 are used after the bending inspection process of the inspection panel 110 is completed and before imaging the pressed surface using the plurality of imaging devices 191, 193. In an embodiment, the plurality of fixing members 151, 153 may be mounted on the inspection panel 110 to fix it to a stationary position.

The bending press member 170 is configured to press in the Z-axis direction perpendicular to the opposing pairs of the plurality of detachable fixing members 151, 153, which move towards the central area along the Y-axis direction, the longitudinal direction of the plurality of detachable fixing members 151, 153.

In an embodiment, the bending press member 170 is detachably coupled to the plurality of detachable fixing members 151, 153, and is installed at both ends of the rotation axes 151a, 151b when the plurality of detachable fixing members 151, 153 are connected to the third and fourth roller parts, to press the inspection panel 110 in the X-axis direction, which is the relatively short side direction of the inspection panel 110.

In an embodiment, the bending press member 170 presses both ends of the rotation axes 151b, 153b of the third and fourth roller parts 151a, 153a in the Y-axis direction, which is the longitudinal side, centered on the central area of the inspection panel 110, and bends the inspection panel 110 to achieve a set curved surface.

In an embodiment, the movement of the bending press member 170 may be controlled in micrometer units.

Therefore, the bending curvature of the inspection panel 110 can be precisely controlled.

In an embodiment, the plurality of imaging devices 190 includes at least four imaging devices 191, 193 arranged at the bottom of each of four vertices where sides of the inspection panel 110 meet, with respect to the inspection panel 110 supported by the plurality of support members 131, 133. However, embodiments of the present disclosure are not necessarily limited thereto and the number of the plurality of imaging devices 190 may vary. For example, in an embodiment the bending inspection device 100 may include two imaging devices 191, 193 arranged at two different corners of the of the inspection panel 110.

The plurality of imaging devices 191, 193 can be used to determine whether the inspection panel 110 has been loaded or unloaded by the loading/unloading device for the bending inspection process, and to input and/or discharge the inspection panel 110 from the correct position before and after the bending inspection process.

The plurality of imaging devices 191, 193 image four corners of the inspection panel 110, respectively, which is supported by the plurality of support members 131, 133 and the plurality of detachable fixing members 151, 153 before and after the bending inspection process. However, embodiments of the present disclosure are not necessarily limited thereto and the plurality of imaging devices 191, 193 may image three or less corners of the inspection panel 110 in some embodiments. Additionally, in some embodiments in which the shape of the inspection panel 110 differs from a rectangular shape, the number of corners or other surfaces of the inspection panel 110 that are imaged by the imaging devices 191, 193 may vary.

By comparing images of the four corners of the inspection panel 110 taken by the plurality of imaging devices 191, 193 before and after the bending inspection process, it can be determined whether to perform a bending defect inspection on the inspection panel 110.

In an embodiment, the bending defect measurement unit 195 senses sound waves generated from the inspection panel 110 during the bending inspection process on the inspection panel 110 loaded on the plurality of support members 131, 133. In an embodiment, the bending defect measurement unit 195 may be a sonic sensor that is built into the plurality of fixing members 151, 153.

The bending defect measurement unit 195 senses the amplitude of the sound wave generated from the inspection panel 110 during the bending inspection process, and detects defects based on the amplitude of the sound wave generated during the bending inspection process.

The bending defect measurement unit 195 may use the plurality of imaging devices 191, 193, and may be positioned in various positions with respect to the inspection panel 110. For instance, in an embodiment the bending defect measurement unit 195 may be located at a horizontal distance or a vertical distance from the central area of the inspection panel 110.

The control device 200 controls the overall automated inspection operation of the bending inspection device 100.

In an embodiment, the control device 200 includes a transfer device control unit 210 that controls a transfer device, which transfers the inspection panel 110 before and after the bending inspection process, and a support member control unit 220, which controls loading on the plurality of the support members 131, 133, as well as fixing and detaching of the inspection panel 110 loaded on the plurality of support members 131, 133. In an embodiment, the control device 200 includes a fixing member control unit 230 that controls the attachment and detachment of the plurality of detachable fixing members 151, 153 to the inspection panel 110, an imaging control unit 240 that captures and stores an image of predetermined positions on the inspection panel 110 using a plurality of imaging devices 191, 193, a pair of the fixing members 151, 153 that perform a bending inspection process by bending the inspection panel 110 to a set inspection curvature, a bending press member control unit 250 that selects the fixing members 151, 153 and aligns the bending press member 170 with respect to the selected pair of fixing members 151, 153 to press them in the Z-axis direction, and a bending defect measurement unit control unit 260 that controls the operation of the bending defect measurement unit 195 when the bending inspection process is started.

In an embodiment, the transfer device 300 includes a support member driving means 310 that rotationally drives the plurality of support members 131, 133 to position the inspection panel 110 correctly during loading or unloading, and may include a fixing member driving means 330 that rotates the plurality of fixing members 151, 153.

The support member driving means 310 and the fixing member driving means 330 may be motors capable of rotating in both a forward direction and a reverse direction.

In an embodiment, the transfer device 300 may include vertical reciprocating means 350 for reciprocating the bending press member 170 in the Z-direction before and after the bending inspection process.

The vertical reciprocating means 350 may include first vertical reciprocating means 351 that drives the bending press member 170 vertically up on the inspection panel 110.

In an embodiment, the vertical reciprocating means 350 may be a conventional pneumatic or hydraulic cylinder.

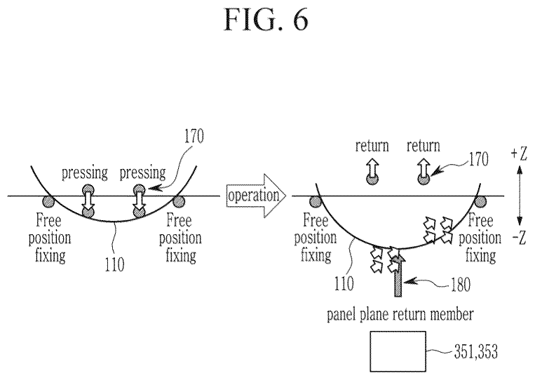

FIG. 6 is a conceptual diagram of an inspection system for the curved display device according to an embodiment of the present disclosure.

As shown in FIG. 6, in the bending inspection process, the bending press member 170 is applied to both sides of the central area in the Y-axis direction of the inspection panel 110 loaded on the plurality of support members 131, 133, to bend the inspection panel 110 to form a curved surface having an inspection curvature.

In an embodiment, when the bending inspection process is completed, the bending press member 170 is moved in the −Z direction, which is opposite to the +Z direction, by the second vertical reciprocating means 353 to release the pressure on the inspection panel 110, after which the bending pressure member 170 returns to the +Z direction, which is opposite to the −Z direction.

Accordingly, the inspection panel 110 is restored from the curved surface to its original surface by movement of the bending pressure member 170 to release the pressure on the inspection panel 110.

However, even though the bending inspection process of the inspection panel 110 is completed, since the inspection panel 110 is not completely restored from the curved surface to its original surface, a panel plane return member 180 may be further included to restore the original surface of the inspection panel 110 from the curved surface of the inspection panel 110.

In an embodiment, the panel plane return member 180 is positioned below the central area of the curved surface of the inspection panel 110 and is configured to press the inspection panel 110 vertically upward.

In an embodiment, the panel plane return member 180 is a bar-shaped pressing member and can be vertically reciprocated by the second vertical reciprocating means 353, which is positioned below the display panel among the vertical reciprocating means 350.

When the panel plane return member 180 returns the curved surface of the inspection panel 110 to its original surface by pressing vertically upward, a force is generated in an oblique direction due to the resultant force between the elastic restoring force of the inspection panel 110 and the vertical upward pressing force of the panel plane return member 180. Consequently, a position deviation may occur when the inspection panel 110 returns to the plane, making it difficult to confirm the pickup position of the panel 110 after the bending inspection process.

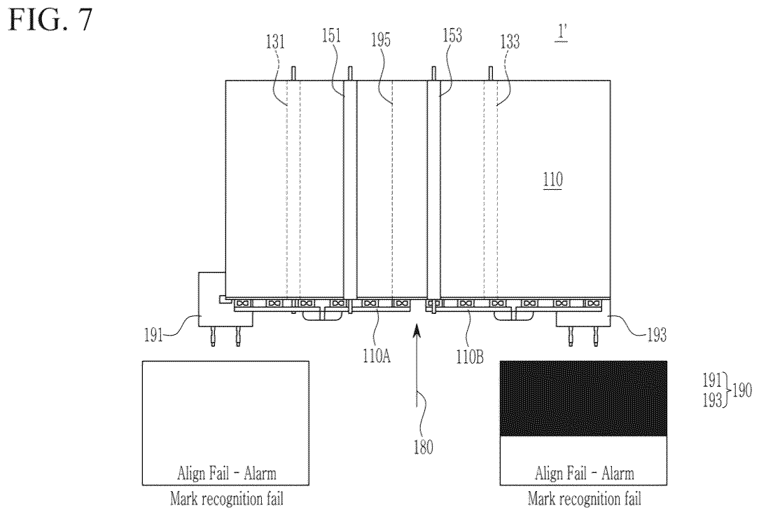

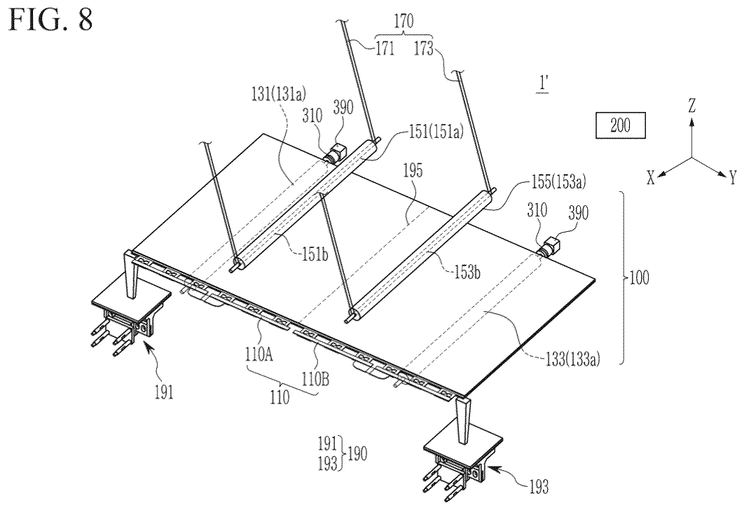

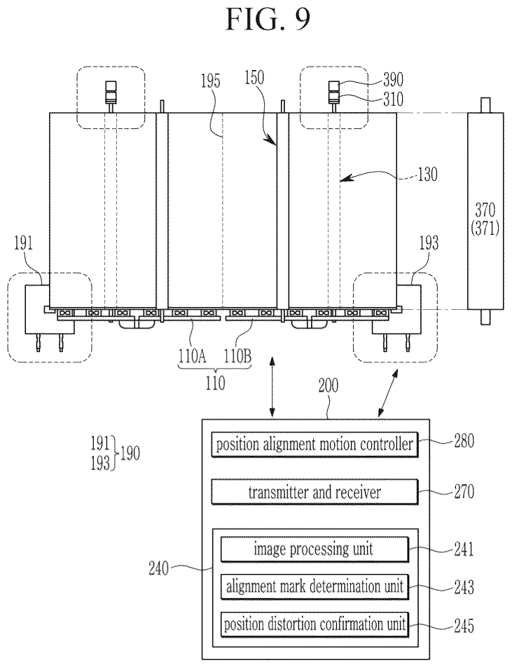

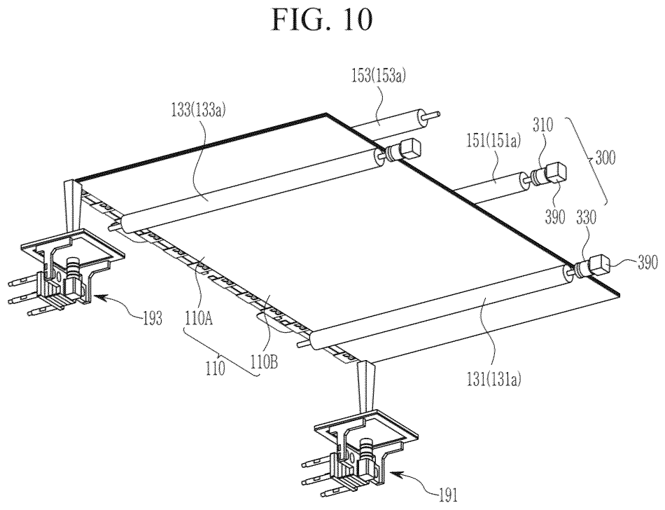

However, the inspection system 1′ of the curved display device according to an embodiment of the present disclosure as shown in FIGS. 6-10, is designed to solve the problems of the inspection system 1 for the curved display device in an embodiment of the present disclosure as shown in FIG. 1. As shown in FIGS. 7 to FIG. 10, the inspection system 1′ includes a plurality of imaging devices 191, 193 capturing images of the four corners of the inspection panel 110, identifying the distorted orientation of the inspection panel 110, and aligning the position of the inspection panel 110 by micro-positioning the position alignment means 390 on the plurality of support members 131, 133.

Hereinafter, the inspection system 1′ for the curved display device according to an embodiment of the present disclosure will be described in detail with reference to FIGS. 7 to FIG. 10.

FIG. 7 to FIG. 10 are a perspective view, a front view, a perspective view from the bottom, and a side view, respectively, of an inspection system for the curved display device according to an embodiment of the present disclosure.

Similar to the curved display device inspection system 1 according to an embodiment of the present disclosure as shown in FIG. 1, the curved display device inspection system 1′ according to an embodiment of the present disclosure in FIGS. 7-10 includes the bending inspection device 100, the inspection panel 110, a plurality of support members 131, 133, a plurality of detachable fixing members 151, 153, bending press members 171, 173, and imaging devices 191, 193.

However, in an embodiment as shown in FIGS. 7-10, the inspection panel 110 is continuously supplied by a loading/unloading device, which may act as a pickup device.

In an embodiment, the gap between the plurality of support members 131, 133 may be arranged to be greater than the gap between the plurality of detachable fixing members 151, 153.

Accordingly, in this embodiment, the inspection panels 110 are supported by the plurality of support members 131, 133, and the bending press members 171, 173 are coupled to the plurality of detachable fixing members 151, 153.

Similar to the inspection system 1 for a curved display device according to an embodiment of the present disclosure as shown in FIG. 1, the curved display device inspection system 1′ according to an embodiment of the present disclosure as shown in FIGS. 6-10 uses the first and second roller parts 131a, 133a as the plurality of support members 131, 133. The inspection panel 110 can be automatically moved before and after the bending defect inspection, and the support member driving means 310, attached to the first and second roller parts 131a, 133a, may be stopped to support the inspection panel 110 during the bending defect inspection.

Similarly, the plurality of detachable fixing members 151, 153 supported by the plurality of support members 131, 133 using the third and fourth roller parts 151a, 153a, respectively, can be fixed to prevent movement, and the inspection panel 110 can be automatically moved before and after the bending defect inspection.

Similarly, the aforementioned first and second roller parts 131a, 133a and the third and fourth roller parts 151a, 151b can be made of a material resistant to static electricity to reduce the occurrence of scratches caused by the movement of the inspection panel 110 in a diagonal direction as opposed to a horizontal direction under the bending inspection conditions.

The plurality of fixing members 151, 153 are used to facilitate the bending inspection process while the inspection panel 110 is bent during the bending inspection process. In an embodiment, the plurality of fixing members 151, 153 can be removed from, moved to, and mounted near the central area where the inspection panel 110 is bent, and the bending press members 171, 173 are coupled to the plurality of fixing members 151, 153 during the bending inspection.

The plurality of fixing members 151, 153 are used after the bending inspection process of the inspection panel 110 is completed and before imaging the pressed surface of the inspection panel 110 using the plurality of imaging devices 191, 193, and they may be mounted on the inspection panel 110 to fix the inspection panel 110 to a stationary position.

The bending press member 170 is configured to be coupled with an opposing pair of the plurality of detachable fixing members 151, 153 installed with respect to the inspection panel 110 in a combined perpendicular Z-axis direction.

In an embodiment, the bending press member 170 is detachably coupled to the plurality of detachable fixing members 151, 153, and is installed around both ends of the rotation axis 151b, 153b when the plurality of detachable fixing members 151, 153 act as the third and fourth roller parts 151a, 153b, uniformly pressing the inspection panel 110 in the X-axis direction, which is the relatively short-side direction of the inspection panel 110.

The bending press member 170 presses both ends of the rotation axes 151b, 153b of the third and fourth roller parts 151a, 153a in the Y-axis direction, which is the longitudinal side, centered on the central area of the inspection panel 110, to bend the inspection panel 110 and achieve a set curved surface.

In an embodiment, the movement of the bending press member 170 may be controlled in micrometer units.

Accordingly, the bending curvature of the inspection panel 110 can be precisely controlled.

In an embodiment, the plurality of imaging devices 191, 193 include at least four imaging devices positioned, respectively, below each of the four vertices where the sides of the inspection panel 110 meet and supported by the plurality of support members 131, 133.

The plurality of imaging devices 191, 193 may image the inspection panel 110 to determine whether a bending defect has occurred in the inspection panel 110 during the bending inspection process. After completing the bending inspection process, the inspection panel 110 may transform from a curved surface to a plane surface (e.g., a flat surface). By the plurality of imaging devices 191, 193 imaging of the inspection panel 110 to determine whether the inspection panel 110 has returned to the plane surface, the inspection panel 110 can be loaded or unloaded at the correct position, thereby automating the bending inspection process.

The bending defect measurement unit 195 may use the plurality of imaging devices 191, 193 and may be positioned at various positions with respect to the inspection panel 110.

For instance, in an embodiment the bending defect measurement unit 195 may be located at a horizontal distance or a vertical distance from the central area of the inspection panel 110.

Similar to the inspection system 1 of the curved display device according to an embodiment of the present disclosure shown in FIGS. 1-5, the inspection system 1′ of the curved display device according to an embodiment of the present disclosure shown in FIGS. 6-10 includes a control device 200. In an embodiment, the control device 200 includes a transfer device control unit 210, a support member control unit 220, a fixed member control unit 230, a bending press member control unit 250, and a bending defect measurement unit control unit 260. In an embodiment, the control device 200 further includes a transceiver unit 270 for transmitting and receiving from the imaging devices 191, 193 and/or the bending defect measurement unit 195, and a position alignment motion control unit 280 for the transportation or unloading of the inspection panel 110 after the bending inspection process based on the gray value of the captured image of the imaging devices 190. In an embodiment, the imaging control unit 240 is linked with (e.g., electrically connected thereto for communication therewith) the position alignment motion control unit 280 to control the position alignment motion of the inspection panel 110 before and after the bending inspection process.

In an embodiment, the imaging control unit 240 includes an image processing unit 241 that processes images captured by the imaging devices 190 of four corners of the inspection panel 110 to enable linkage with the position alignment motion control unit 280, an alignment mark determination unit 243 that determines whether the alignment mark is recognized based on the gray value of the alignment mark captured image, and the position of the inspection panel 110 when the alignment mark determination unit 243 fails to recognize the alignment mark; additionally, it may also include a position misalignment confirmation unit 245 that checks the distortion (e.g., misalignment of the inspection panel 110) based on the gray value of the captured image.

In an embodiment, the transfer device 300 can rotate the plurality of support members 131, 133 to accurately position the inspection panel 110 for loading and unloading.

In an embodiment, the transfer device 300 includes the support member driving means 310 for rotating the support members 131, 133, and the fixing member driving means 330 for rotating the plurality of fixing members 151, 153.

In some embodiments, the support member driving means 310 and the fixing member driving means 330 may be motors capable of rotating in both a forward direction and a reverse direction.

The transfer device 300 may include a vertical reciprocating means 350 for reciprocating the bending press member 170 in the Z direction before and after the bending inspection process. In some embodiments the vertical reciprocating means may be positioned at both the upper and lower surfaces of the inspection panel 110. In some embodiments, a single vertical reciprocating means 350 may be used positioned at an upper or lower surface of the inspection panel 110.

In an embodiment, the transfer device 300 may include a fine position alignment means 390 which operates under the control of the position alignment motion control unit 280 in the control device 200.

The fine position alignment means 390 is installed on the support members 131, 133, and the support member driving means 310 may also be used for positioning the inspection panel 110.

By using the support member driving means 310 as the fine position control means 390, transport, support, and position control motion of the inspection panel 110 can be performed. Thus, the size of the bending inspection defect device 100 can be reduced as well as the costs.

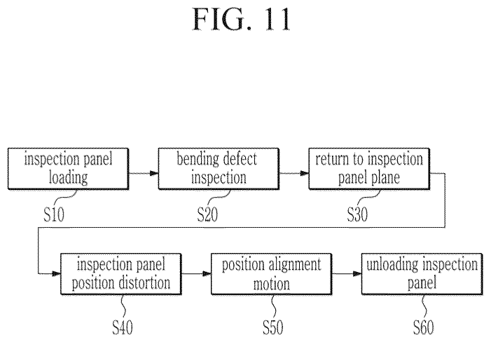

Hereinafter, the control method of a curved display device inspection system according to an embodiment of the present disclosure will be described with reference to FIGS. 11 to 13. FIG. 11 is a simple flowchart of the control method of the curved display device inspection system according to an embodiment of the present disclosure.

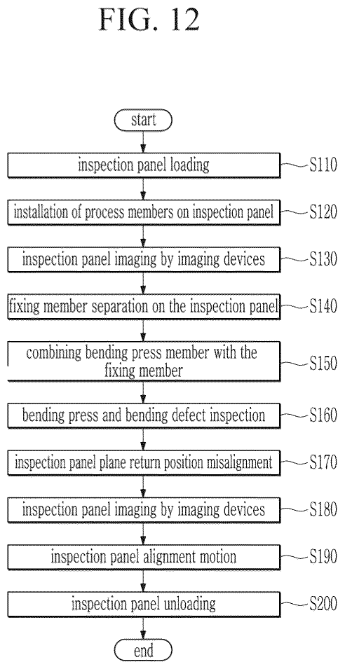

FIG. 12 is a detailed flowchart of the control method of the curved display device inspection system according to an embodiment of the present disclosure.

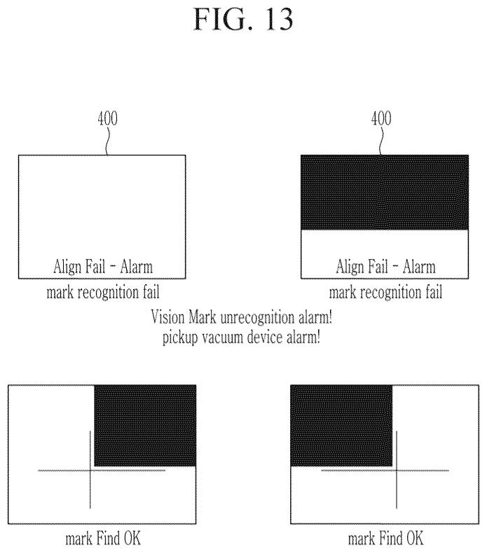

FIG. 13 is a diagram explaining the concept of the position alignment motion method of FIG. 12.

As shown in FIG. 11, the control method of the curved display device inspection system of an embodiment of the present disclosure may include: step S10 which is automatically loading an inspection panel 110 to a proper position of a bending defect inspection device 100 to automate a bending defect inspection of a curved display device, step S20 which is performing a bending defect inspection on the loaded inspection panel 110, step S30 which is restoring the curved surface of the bent inspection panel 110 to a plane surface after the bending defect inspection, step S40 which is confirming the misalignment of the position of the inspection panel 110 that occurred in the process of being restored to a plane surface, step S50 that is a position alignment motion execution in which the misaligned position of the inspection panel 110 is moved in the X-axis direction using the support member driving means 310 of a plurality of support members 131, 133 under the inspection panel 110 to align the position of the inspection panel 110 to a proper position suitable for unloading, and step S60 which is unloading the inspection panel 110 on which the bending defect inspection has been completed using a pickup device.

As shown in FIG. 12, the control method of the curved display device inspection system, according to an embodiment of the present disclosure, controls the control device 200 to load the inspection panel 110 onto the plurality of support members 131, 133 using a pickup device.

In step S110, the control device 200 may load the inspection panel 110 onto the plurality of support members 131, 133.

In step S120, the control device 200 uses the plurality of detachable fixing members 151, 153 to fix the inspection panel 110, which is loaded on the plurality of support members 131, 133 to the inspection panel 110, and each of the support members 131, 133 is mounted on the upper part to be less than the gap between them.

In step S130, the control device 200 uses a plurality of imaging devices 191, 193 to image four corners of the inspection panel 110 fixed by the plurality of detachable fixing members 151, 153, and the control device 200 stores the captured images of the four corners of the inspection panel 110.

In step S140, the plurality of detachable fixing members 151, 153 are detached (e.g., separated) from the inspection panel 110. In step S150, the controller 200 couples the bending press member 170 to both edges of the fixing members 150 to perform a bending test process to bend the inspection panel 110 to a set (e.g., predetermined) inspection curvature. In step S160, bending pressure is applied in the Z-axis direction, and the controller 200 operates the bending defect measurement unit 195 to perform a bending defect inspection.

In an embodiment, in the bending inspection process, the bending press member 170 presses adjacent to the central area in the Y-axis direction of the inspection panel 110, which is loaded on the roller portions of the plurality of support members 131, 133. Thereby the inspection panel 110 bends to the inspection curvature, forming a curved surface.

When the bending inspection process is completed, the control device 200 stops the operation of the bending defect measurement unit 195 and releases the bending press member 170 by moving it in the −Z direction, which is opposite to the +Z direction, while the panel plane return member 180 restores the central area of the inspection panel 110 from the curved surface to the original surface in step S170.

Then, the inspection panel 110 may be misaligned in the X-axis direction due to the resultant force in the Z-axis direction and the Y-axis direction due to the panel plane return member 180.

In step S180, the control device 200 uses the plurality of detachable fixing members 151, 153 to fix the inspection panel 110 loaded on the plurality of support members 131, 133 after the bending inspection process is performed. When both edges of the inspection panel 110 are fixed, the four corner lower surfaces of the inspection panel 110 are imaged using a plurality of imaging devices 191, 193, and the four corner captured images are stored after bending.

In step S190, the control device 200 determines whether the inspection panel 110 is out of position after the bending inspection process by comparing the four corner images taken before and after the bending inspection process. The control device 200 then determines the correct position of the inspection panel 110 for loading and aligning the inspection panel position.

In step S200, the control device 200 can check the alignment motion and unload the inspection panel 110 in the correct position using the pickup device.

As shown in FIG. 13, the position alignment motion method of FIG. 12 involves capturing (e.g., imaging) the four corners of the inspection panel 110, which is fixedly supported by the plurality of supports 131, 133 and the plurality of detachable fasteners 151, 153, before and after the bending inspection process using the plurality of imaging devices 191, 193. The presence of alignment marks in the image processed by the image processing unit 241 is determined by the alignment mark determination unit 243. In an embodiment, the direction of misalignment of the inspection panel 110 is confirmed through the misalignment confirmation unit 245 based on the gray value of the alignment mark in the image processed by the image processing unit 241. If no alignment mark is detected in the image, failure to recognize the alignment mark can be displayed on the management terminal 400.

The management terminal 400 displays an alignment mark recognition failure alarm for the pickup or placement device, which uses vacuum suction to pick up and place the inspection panel 110, prompting alignment of the inspection panel 110.

According to the above embodiment, inspection of bending defects in an inspection panel can be automated using an inspection device.

Additionally, by comparing the images of the four corners of the inspection panel captured before and after the bending inspection process, the positional distortion occurred by returning the curved surface of the inspection panel to a plane surface after bending can be corrected using the driving means of the support members positioned at the bottom of the inspection panel.

Accordingly, the inspection of bending defects in flexible curved display panels used in curved display devices can be automated.

What is claimed is:

1. An inspection system for a display device, the inspection system includes:
a plurality of support members supporting a bottom of an inspection panel of the display device;
a plurality of imaging devices that captures images of four corners of the inspection panel;
a position misalignment confirmation unit verifying a misaligned direction of the inspection panel based on gray values of the four corner images of the inspection panel; and
a control unit that corrects a misalignment of the inspection panel determined by the position misalignment confirmation unit, the control unit controlling support member driving means that drives the plurality of support members to correct the misalignment.

2. The inspection system for the display device of claim 1, wherein:
the support member driving means moves the inspection panel in an X-axis direction to correct the misalignment of the inspection panel, wherein the misalignment is caused by a resultant force in a Z-axis direction and a Y-axis direction when the inspection panel is restored from a curved surface during the bending inspection process to a plane surface after the bending inspection process.

3. An inspection system for a display device, comprising:
a bending inspection device that inspects a bending defect of an inspection panel of the display device;
a transfer device that loads, moves, and unloads the inspection panel to the bending inspection device;
a control device that controls the bending inspection device and the transfer device,
wherein the bending inspection device includes a pair of upper rollers fixing an upper portion of the inspection panel, a pair of lower rollers supporting a lower portion of the inspection panel, a bending press member that presses the upper roller vertically downward to bend the inspection panel, and a plane return member that returns a curved surface of the inspection panel to a plane surface after a process for inspecting defective bending of the inspection panel.

4. The inspection system for the display device of claim 3, wherein:
the plane return member is positioned below the inspection panel, and an imaging device is mounted at the bottom of each of four corners of the inspection panel.

5. The inspection system for the display device of claim 4, wherein:
the imaging device detects a bending defect of the inspection panel and simultaneously detects alignment of the four corners of the inspection panel based on a gray value of images of the inspection panel captured by the imaging device.

6. The inspection system for the display device of claim 4, wherein:
the pair of lower rollers is mounted at an edge in the y-axis direction that is a longitudinal direction of the inspection panel, and a pair of fixed rollers is mounted closer to a center in the y-axis direction than the pair of lower rollers.

7. The inspection system for the display device of claim 4, wherein:
a lower roller driving means is positioned on a rotation axis of the pair of lower rollers, and the lower roller driving means aligns and moves at least one of the four corners of the inspection panel in conjunction with images captured by the imaging device.

8. The inspection system for the display device of claim 4, wherein:
the bending press member is detachable from the pair of upper rollers and is coupled to both ends of the pair of upper rollers at a top of the inspection panel.

9. The inspection system for the display device of claim 8, wherein:
the bending press member and the plane return member are positioned at an upper and lower surface of the inspection panel, respectively; and
the display device further includes first and second vertical reciprocating drive means for reciprocating the bending press member vertically up and down, respectively.

10. The inspection system for the display device of claim 3, wherein:
the control device comprises a transfer device control unit that controls the transfer device, a loading control unit that controls loading of the inspection panel on the pair of lower rollers, a fixing member control unit that controls fixing of the inspection panel by the pair of upper rollers, and an imaging control unit that controls imaging devices to capture images of each of four corners of the inspection panel, a bending press member control unit that controls the pressing of the upper roller by the bending press member in response to bending conditions of the inspection panel, and a bending defect control unit that measures and controls the bending defect of the inspection panel.

11. The inspection system for the display device of claim 10, further comprising:
a transceiver unit that transmits and receives data from the imaging devices and the bending defect measurement unit; and
a position alignment control unit that controls transfer or unloading of the inspection panel to a correct position after the bending inspection process based on a gray value of the images captured image by the imaging devices.

12. The inspection system for the display device of claim 11, wherein:
the imaging control unit includes an image processing unit that processes the images captured by the imaging devices and is connected to the position alignment control unit, the imaging control unit determines whether or not an alignment mark is recognized in the four corners of the inspection panel based on the gray values, and a position misalignment conformation unit that checks a misalignment of the inspection panel based on the gray values when the alignment mark determination unit fails to recognize the alignment mark.

13. The inspection system for the display device of claim 12, wherein:
the transfer device includes support member driving means for rotating a support member supporting a bottom of the inspection panel, a fixing member driving means for rotating the pair of upper rollers, and a vertical reciprocating means for reciprocating the bending press member in the vertical direction,
and the support member driving means comprises a fine position alignment means for fine alignment in the x-axis direction under control of the position alignment motion control unit.

14. A control method of a display device inspection system, comprising:
automatically loading an inspection panel into a correct position on the display device inspection system;
performing a bending inspection process on the loaded inspection panel, the loaded inspection panel is bent to have a curved surface during the bending inspection process;
performing a process to return the curved surface of the inspection panel to a plane surface after performing the bending inspection process;
checking a position misalignment of the inspection panel that occurred during the process of returning the inspection panel to the plane surface;
performing a position alignment movement to correct the position misalignment of the inspection panel and place the inspection panel into a correct position; and
unloading the inspection panel in the correct position.

15. The control method of the display device inspection system of claim 14, wherein:
the automatic loading of the correct position comprises arranging a pair of support members supporting the inspection panel from a bottom of the inspection panel,
and the bending inspection process comprises pressing the inspection panel from above by a bending press member, while pressing a pair of fixing members positioned in a central area of the inspection panel, the pair of fixing members has a gap less than a gap between the pair of support members.

16. The control method of the display device inspection system of claim 15, wherein:
the process of returning to the plane surface is performed by returning the bending press member upward and a plane returning member pressing the curved surface of the inspection panel to the plane surface from the bottom to a top of the inspection panel.

17. The control method of the display device inspection system of claim 14, wherein:
the checking of the position misalignment of the inspection panel comprises imaging four corners of the inspection panel before and after the bending inspection process by imaging devices positioned below the four corners of the inspection panel, and the position misalignment is determined based on a gray value of the captured images.

18. The control method of the display device inspection system of claim 17, wherein:
the checking of the position misalignment of the inspection panel comprises registering a reference mark, photographing and registering the reference mark with the four corners of the inspection panel aligned before the bending inspection process;
imaging the alignment mark of the inspection panel after the bending inspection process by photographing the four corners of the inspection panel after the bending inspection process; and
comparing gray values of the reference mark aligned before the bending inspection process with the alignment mark and moving the inspection panel in the X-axis direction using a support member driving means to perform a position alignment movement of the inspection panel.
